(19) United States
(12) Patent Application Publication
(10) Pub. No.: US 2020/0165171 A1
(43) Pub. Date: May 28, 2020

(54) METHOD FOR PRODUCING LAYERS OF SILICON CARBIDE

(71) Applicant: PSC Technologies GmbH, Berlin (DE)

(72) Inventors: Siegmund GREULICH-WEBER, Bad Lippspringe (DE); Rüdiger SCHLEICHER-TAPPESER, Berlin (DE)

(73) Assignee: PSC Technologies GmbH, Berlin (DE)

(21) Appl. No.: 16/620,617

(22) PCT Filed: Jun. 4, 2018
(86) PCT No.: PCT/EP2018/064621

§ 371 Date: Dec. 9, 2019

(30) Foreign Application Priority Data
Jun. 9, 2017 (DE) 10 2017 112 756.9

(51) Int. Cl. C04B 41/50; C04B 41/45; C04B 41/00; C30B 1/02; C30B 29/36

(52) U.S. Cl. CPC C04B 41/5059; C04B 41/4537; C04B 41/455; C04B 2111/0025; C30B 1/023; C30B 29/36; C04B 41/009; C04B 41/0072

(57) ABSTRACT

The invention relates to a method for producing thin layers of silicon carbide by means of a solution or dispersion containing carbon and silicon.

### CROSS-REFERENCES TO RELATED APPLICATIONS

This application is a National Stage filing of International Application PCT/EP 2018/064621, filed Jun. 4, 2018, entitled METHOD FOR PRODUCING LAYERS OF SILICON CARBIDE, claiming priority to DE 10 2017 112 756.9, filed Jun. 9, 2017. The subject application claims priority to PCT/EP 2018/064621 and to DE 10 2017 112 756.9 and incorporates all by reference herein, in their entirety.

### BACKGROUND OF THE INVENTION

The present invention relates to the technical field of semiconductor technology. In particular, the present invention relates to a method for producing thin layers of silicon carbide.

Furthermore, the present invention relates to a composition, in particular a silicon carbide precursor sol, for the production of thin layers of silicon carbide.

Finally, the present invention relates to thin layers of silicon carbide.

Silicon carbide, with the formula SiC, is an extremely interesting and versatile material in semiconductor technology and for the production of ceramic materials. Due to its high hardness and high melting point, silicon carbide, which is also called carborundum, is often used as an abrasive or insulator in high-temperature reactors. In addition, silicon carbide forms alloys or alloy-like compounds with a number of elements and compounds which possess a variety of advantageous material properties, such as high hardness, high resistance, low weight and low sensitivity to oxidation, even at high temperatures.

Of particular importance, however, are semiconductor applications, since silicon carbide is mechanically and thermally extremely resistant and the electronic properties can be tailored to the respective application by suitable doping. While pure silicon carbide is an insulator, but due to its good thermal conductivity it is suitable as a substrate for semiconductor structures. Excellent semiconductor materials can be provided by means of suitable doping, especially with the elements boron, aluminum, nitrogen and phosphorus, which can be used at temperatures of up to about 500° C.

Single crystal silicon carbide structures, in particular thin layers of single crystal silicon carbide, are usually required for semiconductor applications. Although a number of processes are currently known to produce thin silicon carbide layers, the processes are often very complex and cost-intensive, which is why the use of silicon carbide in semiconductor technology is limited to only a few special applications.

DE 27 27 557 A1 describes a process for the formation of monocrystalline silicon carbide on a monocrystalline silicon substrate, wherein at least part of the monocrystalline silicon substrate is converted into porous silicon by anode treatment in an aqueous hydrofluoric acid solution. The resulting structure is heated to a temperature in the range from 1,050° C. to 1,250° C. in an atmosphere containing a hydrocarbon gas, so that the porous silicon reacts with the gas portions to form a monocrystalline silicon carbide layer and a polycrystalline silicon carbide layer covering the same.

The scientific publication N. Singh, K. Singh, A. Pandey and D. Kaur, “Improved electrical transport properties in high quality nanocrystalline silicon carbide (nc-SiC) thin films for microelectronic applications”, Materials Letters, 164, 2016, pages 28 to 31, concerns the production of thin layers of nanocrystalline silicon carbide which are applied by sputtering.

Moreover, the scientific publication H. Shen, T. Wu, Y. Pan, L. Zhang, B. Cheng and Z. Yue, “Structural and optical properties of nc-3C—SiC films synthesized by hot wire chemical vapor deposition from SiH4-C2H2-H2 mixture”, Thin Solid Films, 522, 2012, pages 36 to 39, concerns the deposition of nanocrystalline silicon carbide films by CVD methods (Chemical Vapor Deposition).

However, the methods described above are all very complex and can only be used on very cost-intensive crystalline substrates if defined silicon carbide layers with a small number of defects are to be produced.

The WO 96/24709 A1 describes a process for the production of monocrystalline thin silicon carbide layers, in which a substrate to be coated is covered with a carbon-containing polysilane. The adhering layer is pyrolyzed under inert gas and the amorphous silicon carbide layer thus produced is crystallized by maintaining a high temperature of more than 700° C. The described process represents an advanced development of the previously described methods, since relatively thick layers can be produced in short time, but the production of the corresponding polysilanes is very complex and only crystalline substrates can be used as substrates.

In particular, the use of exclusively crystalline substrates is problematic, since monocrystalline substrates, on which the silicon carbide layer is to be produced, are very cost-intensive to manufacture and the material costs for the substrate exceed by far the costs for carrying out the actual process. This is particularly unfavorable if the substrate is not to be reused, but only serves as a carrier material in the production of silicon carbide layers.

Therefore, the state of the art still lacks a simple and cost-effective process for the production of monocrystalline silicon carbide-containing layers or monocrystalline silicon carbide-containing bodies.

### BRIEF SUMMARY OF THE INVENTION

It is therefore an objective of the present invention to avoid or at least mitigate the disadvantages and problems associated with the state of the art described above.

Another objective of the present invention is to provide suitable substances, especially precursors, which can be quickly and reproducibly converted to silicon carbide single crystals on an industrial scale.

Furthermore, an objective of the present invention is to provide a method and suitable starting materials which make it possible to produce layers of silicon carbide on non-crystalline substrates, in particular on non-monocrystalline substrates.

Subject of the present invention according to a first aspect of the present invention is a method for producing thin layers of silicon carbide according to the current disclosure; further advantageous features of the present invention are similarly disclosed.

Another subject of the present invention according to a second aspect of the present invention is a composition also disclosed; further, advantageous embodiments of this aspect of the invention are provided.

Finally, a further subject of the present invention is a silicon carbide layer.

It goes without saying that the particular features mentioned in the following, in particular special embodiments or the like, which are only described in relation to one aspect of the invention, also apply in relation to the other aspects of the invention, without this requiring any express mention.

Furthermore, for all relative or percentage, in particular weight-related, quantities or amounts stated below, it is to be noted that, within the framework of this invention, these are to be selected by the person skilled in the art in such a way that the sum of the ingredients, additives or auxiliary substances or the like always results in 100 percent or 100 percent by weight. This, however, goes without saying for the person skilled in the art.

In addition, the skilled person may deviate from the values, ranges or quantities listed below, depending on the application and individual case, without leaving the scope of this invention.

In addition, all of the parameters specified below or the like can be determined by standardized or explicitly specified determination methods or by common determination methods known per se by the person skilled in the art.

### DETAILED DESCRIPTION OF THE INVENTION

With this provision made, the subject-matter of the present invention is explained in more detail in the following.

Subject of the present invention—according to a first aspect of the present invention—is thus a method for producing thin layers of silicon carbide, wherein
(a) in a first method step, a liquid carbon- and silicon-containing solution or dispersion, in particular a SiC precursor sol, is applied to a substrate and
(b) in a second method step following the first method step (a), the carbon- and silicon-containing solution or dispersion, in particular the SiC precursor sol, is converted to silicon carbide.

As was surprisingly found by applicant, the use of carbon- and silicon-containing solutions or dispersions, in particular SiC precursor sols, allows the production of thin layers of doped or non-doped silicon carbide which have an extremely low number of defects and are excellently suited for semiconductor applications.

In addition, the invention allows the production of thin layers of silicon carbide on almost all substrates, and not only on monocrystalline substrates such as silicon carbide or silicon wafers. In particular, the present invention also permits the removal of the substrate after formation of the thin layer of silicon carbide.

Repeated application of the method according to the invention enables, in particular, the production of several layers of monocrystalline silicon carbide, so that finally silicon carbide wafers are also accessible by the method according to the invention.

The inventive method allows the simple, cost-effective and reproducible production of thin layers of silicon carbide or silicon carbide bodies with a flat surface.

In the context of this invention, it is generally intended that the layer of silicon carbide has a thickness of 0.1 to 1,000 μm, in particular 0.1 to 500 μm, preferably 0.1 to 300 μm, more preferably 0.1 to 10 μm.

In the context of the present invention, a carbon- and silicon-containing solution and dispersion denotes a solution or dispersion, in particular a precursor sol, which contains carbon- and silicon-containing chemical compounds, wherein the individual compounds may contain carbon and/or silicon. The compounds containing carbon and silicon are preferably suitable as precursors for the target compounds to be produced.

In the context of the present invention, a precursor is a chemical compound or a mixture of chemical compounds which react by chemical reaction and/or under the action of energy to form one or more target compounds.

In the context of the present invention, a precursor sol is a solution or dispersion of precursor substances, in particular starting compounds, preferably precursors, which react to the desired target compounds. In precursor sols, the chemical compounds or mixtures of chemical compounds no longer necessarily exist in the form of the chemical compounds originally used, but, for example, as hydrolysis, condensation or other reaction or intermediate products. This is, however, also illustrated by the expression “sol”. In sol-gel processes, inorganic materials are usually converted by hydrolysis or solvolysis into reactive intermediates or agglomerates and particles, the so-called sol, which then age into a gel, particularly through condensation reactions, resulting in larger particles and agglomerates in the solution or dispersion.

In the context of this invention, a SiC precursor sol is a sol, in particular a solution or dispersion, which contains chemical compounds or their reaction products, from which silicon carbide can be obtained under process conditions.

In the context of this invention, a solution is to be understood as a conventional liquid single-phase system in which at least one substance, in particular a compound or its building blocks, such as ions, are homogeneously distributed in another substance, the so-called solvent. In the context of the present invention, a dispersion is to be understood as an at least two-phase system in which a first phase, namely the dispersed phase, is distributed in a second phase, the continuous phase. The continuous phase is also referred to as the dispersion medium; in the context of the present invention the continuous phase is usually in the form of a liquid and dispersions are generally solid-liquid dispersions. Especially in the case of sols or polymeric compounds, however, the transition from a solution to a dispersion is often fluid and it is no longer possible to distinguish clearly between a solution and a dispersion.

In the context of this invention, a layer is defined as a distribution of material, in particular in the form of a single crystal, with a certain layer thickness in one plane, in particular on a surface of a substrate. The layer does not have to be completely covered with the material. Usually, however, at least one surface of the substrate is completely covered with the layer of silicon carbide or with a layer of the carbon- and silicon-containing solution or dispersion.

In the context of the present invention, a substrate is the material to which the carbon- and silicon-containing solution or dispersion, in particular the SiC precursor sol, is applied. In particular, a substrate in the context of the present invention is a three-dimensional or almost two-dimensional structure with at least one preferably flat surface to which the carbon- and silicon-containing solution or dispersion is applied. The substrate is therefore preferably a carrier material to produce the layer of silicon carbide from the formless carbon- and silicon-containing solution.

The silicon carbide produced in the context of the present invention is, as explained above, either doped silicon carbide or non-doped silicon carbide, the silicon carbide preferably being in monocrystalline form. Single crystals in particular are suitable for use in semiconductor technology.

A doped silicon carbide is understood to be a silicon carbide which is mixed with further elements, especially from the 13th and 15th group of the Periodic Table of the Elements, in small amounts, especially doped. The silicon carbide preferably has at least one doping element in the ppm (parts per million) or ppb (parts per billion) range. The doping of the silicon carbides has a decisive influence on the electrical properties of the silicon carbides in particular, so that doped silicon carbides are particularly suitable for applications in semiconductor technology. Dopants with doping elements having more than 4 valence electrons are referred to as n-dopants, while dopants with doping elements having less than 4 valence electrons are referred to as p-dopants.

Usually, the silicon carbide is doped with an element selected from the group of nitrogen, phosphorus, arsenic, antimony, boron, aluminum, gallium, indium and their mixtures. Preferably, the silicon carbide is doped with elements of the 13th and 15th group of the Periodic Table of the Elements, whereby in particular the electrical properties of the silicon carbide can be specifically manipulated and adjusted. Such doped silicon carbides are particularly suitable for applications in semiconductor technology.

If the silicon carbide is doped in the context of the present invention, it has proven successful if the doped silicon carbide contains the doping element in quantities of 0.000001 to 0.0005 wt. %, in particular 0.000001 to 0.0001 wt. %, preferably 0.000005 to 0.0001 wt. %, more preferably 0.000005 to 0.00005 wt. %, based on the doped silicon carbide. For the targeted adjustment of the electrical properties of the silicon carbide, extremely small amounts of doping elements are therefore completely sufficient.

If the silicon carbide is to be doped with nitrogen, nitric acid, ammonium chloride or melamine, for example, can be used as doping reagents. In the case of nitrogen, it is also possible to carry out the process of producing the silicon carbide in a nitrogen atmosphere, in which case doping with nitrogen can also be achieved, although this is less precise.

In addition, doping with alkali metal nitrates, for example, can also be achieved. However, due to the alkali metals which remain in the precursor granulate such doping is less preferred.

If a doping with phosphorus is to be carried out, it has proven to be successful if a doping with phosphoric acid is carried out.

If doping with arsenic or antimony is to be carried out, it has proven successful if the doping reagent is selected from arsenic trichloride, antimony chloride, arsenic oxide or antimony oxide.

If aluminum is to be used as a doping element, aluminum powder can be used as a doping reagent, in particular for acid or basic pH values. In addition, it is also possible to use aluminum chlorides. In general, when using metals as doping elements, it is always possible to use chlorides, nitrates, acetates, acetylacetonates, formates, alkoxides and hydroxides—with the exception of sparingly soluble hydroxides.

If boron is used as doping element, the doping reagent is usually boric acid.

If indium is used as doping element, the doping reagent is usually selected from indium halides, especially indium trichloride (InCl₃).

If gallium is used as doping element, the doping reagent is usually selected from gallium halides, in particular GaCl₃.

In the context of the present invention, it is usually provided that in the first method step (a) the carbon- and silicon-containing solution or dispersion, in particular the SiC precursor sol, is applied to the substrate as a layer, in particular as a homogeneous layer. By applying the carbon- and silicon-containing solution or dispersion, in particular the SiC precursor sol, in the form of a layer on the substrate, homogeneous monocrystalline layers of silicon carbide can be obtained.

The carbon- and silicon-containing solution or dispersion can be applied to the substrate by any suitable process. However, it has proven effective if in method step (a) the carbon- and silicon-containing solution or dispersion, in particular the SiC precursor sol, is applied to the substrate by a coating process, in particular by immersion, also called dip-coating, spin-coating, spraying, rolling or by rollers. Particularly good results are obtained if the carbon- and silicon-containing solution or dispersion, especially the SiC precursor sol, is applied to the substrate by immersion, spin-coating or spraying, preferably by immersion.

As far as the layer thickness is concerned, with which the carbon- and silicon-containing solution or dispersion, in particular the SiC precursor sol, is applied to the substrate, this can vary widely depending on the intended use of the silicon carbide and the chemical composition of the silicon carbide. Usually, in method step (a) the carbon- and silicon-containing solution or dispersion, in particular the SiC precursor sol, is applied to the substrate with a layer thickness in the range from 0.1 to 1,000 μm, in particular from 0.1 to 500 μm, preferably from 0.1 to 300 μm, more preferably from 0.1 to 10 μm.

Furthermore, in the context of the present invention it can be provided that the carbon- and silicon-containing solution or dispersion, in particular the SiC precursor sol, has a dynamic viscosity according to Brookfield at 25° C. in the range from 3 to 500 mPas, in particular from 4 to 200 mPas, preferably from 5 to 100 mPas. If the carbon- and silicon-containing solution or dispersion, in particular the SiC precursor sol, has dynamic viscosities in the aforementioned ranges, the layer thicknesses with which the carbon- and silicon-containing solution is applied to the substrate can be varied in wide ranges. In particular, very high layer thicknesses can be achieved with a single application of the carbon- and silicon-containing solution. These are advantageous, for example, in the production of silicon carbide wafers, since the wafer is accessible in only a few operations.

According to a preferred embodiment of the present invention, the carbon- and silicon-containing solution or dispersion, in particular, the SiC precursor sol, contains
(A) at least one silicon-containing compound,
(B) at least one carbon-containing compound; and
(C) at least one solvent or dispersant.

In the context of this invention, the carbon- and silicon-containing solution or dispersion, in particular the SiC precursor sol, contains special precursors which release silicon under the process conditions and special precursors which release carbon under the process conditions. In this way, the ratio of carbon to silicon in the carbon- and silicon-containing solution or dispersions can be easily varied and tailored to the respective application.

Particularly good results are obtained in the context of the present invention if the silicon-containing compound is selected from silanes, silane hydrolysates, orthosilicic acid and their mixtures. The silicon-containing compound is particularly preferred a silane.

Similarly, in the context of the present invention, it has proven reliable if the carbon-containing compound is selected from the group of sugars, in particular sucrose, glucose, fructose, invert sugar, maltose; starch; starch derivatives; organic polymers, in particular phenol-formaldehyde resin and resorcinol-formaldehyde resin, and their mixtures.

As far as the ratio of silicon to carbon in the carbon- and silicon-containing solution or dispersion is concerned, this can naturally vary over a wide range. However, it has proven advantageous if the carbon- and silicon-containing solution or dispersion, in particular the SiC precursor sol, has a weight-related ratio of silicon to carbon in the range from 1:1 to 1:10, in particular 1:2 to 1:7, preferably 1:3 to 1:5, preferably 1:3.5 to 1:4.5. Particularly good results are obtained in the context of this invention if the ratio by weight of silicon to carbon in the carbon- and silicon-containing solution or dispersion, especially in the SiC precursor sol, is 1:4. With the aforementioned ratios of silicon to carbon, silicon carbide monocrystals, especially monocrystalline silicon carbide layers, can be produced in a targeted and reproducible manner, in particular in a subsequent thermal treatment.

Furthermore, the present invention may provide that the carbon- and silicon-containing solution or dispersion, in particular the SiC precursor sol, contains doping reagents. For applications in semiconductor technology in particular, doping of the silicon carbide with elements from the 13th and 15th group of the Periodic Table of the Elements is common in order to generate semiconductor properties in the silicon carbide material, as already described above. However, pure silicon carbide can be used as an insulator, for example.

As far as the substrate on which the silicon- and carbon-containing solution or dispersion, in particular the SiC precursor sol, is applied to is concerned, this can be selected from a variety of suitable materials. In the context of this invention it is possible that the substrate is selected from crystalline and amorphous substrates. According to a preferred embodiment of the present invention, the substrate is an amorphous substrate. It is a special feature of the present invention that the silicon carbide layers do not have to be produced exclusively on crystalline substrates, in particular monocrystalline substrates, but that much cheaper amorphous substrates can also be used.

As far as the material of which the substrate consists is concerned, particularly good results are obtained if the material is selected from carbon, in particular graphite, and ceramic materials, in particular silicon carbide, silicon dioxide, aluminum oxide as well as metals and their mixtures.

However, particularly good results are obtained in the context of the present invention if the material of the substrate is carbon, especially graphite. The use of graphite substrates, in particular, makes it particularly easy and cost-effective to produce thin layers of silicon carbide or silicon carbide wafers. Further suitable materials and substrate materials are for example silicon oxide, especially silicon dioxide wafers, aluminum oxide, for example in the form of sapphire, as well as metals or metallized surfaces, which consist of monocrystalline materials, especially silicon carbide or silicon dioxide wafers, on which a metal, for example platinum, is evaporated.

In general, in method step (b), the carbon- and silicon-containing solution or dispersion, in particular the SiC precursor sol, after application to the substrate, is subjected to a thermal treatment, in particular a multi-stage thermal treatment. The thermal treatment, in particular the multi-stage thermal treatment, turns the carbon- and silicon-containing solution or dispersion, in particular the SiC precursor sol, into a monocrystalline silicon carbide layer.

In accordance with a preferred embodiment of the present invention, during the thermal treatment
(i) in a first thermal treatment stage, the carbon- and silicon-containing solution or dispersion, in particular the SiC precursor sol, is heated to temperatures in the range from 800 to 1,200° C., in particular 900 to 1,100° C., preferably 950 to 1,050° C., and
(ii) in a second thermal treatment stage following the first thermal treatment stage (i), the carbon- and silicon-containing solution or dispersion, in particular the SiC precursor sol, is heated to temperatures of 1,800° C. or higher.

By an at least two-stage thermal treatment in method step (b), the carbon- and silicon-containing solution or dispersion is converted particularly gently and completely into monocrystalline silicon carbide which has only an extremely small number of defects.

In the first thermal treatment stage (i), the carbon- and silicon-containing solution or dispersion, in particular the SiC precursor sol, is usually converted into a glass. Heating in the first thermal process stage removes in particular the solvents and dispersants as well as other volatile substances and pyrolyzes the non-volatile components of the carbon- and silicon-containing solutions or dispersions. Pyrolysis preferably leaves behind a glass in which silicon and carbon are present in high concentrations. In the context of this invention, a glass is to be understood as an amorphous solid which has a near order, but no long-range order. A glass is in particular a solidified melt.

Regarding the time period in which the carbon- and silicon-containing solution or dispersion, in particular the SiC precursor sol, is heated in process stage (i), this can vary naturally in wide ranges. It has, however, proven effective in the context of the present invention if, in the first thermal treatment stage (i), the carbon- and silicon-containing solution or dispersion, in particular the SiC precursor sol, is heated for a period of less than 15 minutes, in particular less than 10 minutes, preferably less than 7 minutes, more preferably less than 5 minutes.

Similarly, it may be provided in the context of the present invention that in process step (i) the carbon- and silicon-containing solution or dispersion, in particular the SiC precursor sol, is heated for a period of 0.5 to 15 minutes, in particular 1 to 10 minutes, preferably 1.5 to 7 minutes, more preferably 2 to 5 minutes. As a result of the relatively short heating times in the thermal treatment stage (i) within the scope of the present invention, sufficient pyrolysis of the starting compounds, in particular of the SiC precursors, but no crystallization to silicon carbide is achieved.

Usually, in treatment stage (ii), the carbon- and silicon-containing solution or dispersion, in particular the SiC precursor sol, preferably the glass obtained in treatment stage (i), is converted into crystalline silicon carbide, preferably monocrystalline silicon carbide.

In the context of the present invention, it has proven to be advantageous if, in the first thermal treatment stage (i), the carbon- and silicon-containing solution or dispersion is pyrolyzed and converted to a glass and, in a subsequent separate treatment stage, in particular in the second thermal treatment stage (ii), the crystallization and production of the silicon carbide single crystals takes place. In this way, particularly pure silicon carbide single crystals with a small proportion of defect structures can be obtained. In particular, it is possible to adjust the polytype of the silicon carbide by suitable temperature selection during the second thermal treatment stage (ii). For example, at a temperature of 1,800° C. in the second treatment stage (ii), the polytype 3C—SiC is obtained, and at temperatures above 2,100° C. in the second thermal treatment stage (ii) the hexagonal SiC polytypes, namely 4H—SiC and 6H—SiC, are obtained.

As regards the period for which the carbon- and silicon-containing solution or dispersion, in particular the glass obtained in stage (i), is heated in stage (ii), this may vary widely. Usually, in treatment stage (ii), the solution or dispersion containing carbon and silicon, in particular the SiC precursor sol, preferably the glass obtained in treatment stage (i), is heated for a period of more than 10 minutes, in particular more than 15 minutes, preferably more than 20 minutes, more preferably more than 25 minutes.

Similarly, the present invention may provide that the carbon- and silicon-containing solution or dispersion, in particular the SiC precursor sol, preferably the glass obtained in treatment stage (i), is heated in treatment stage (ii) for a period of 10 to 50 minutes, in particular 15 to 40 minutes, preferably 20 to 35 minutes, more preferably 25 to 35 minutes. The above periods are sufficient to obtain a complete conversion of the precursors into silicon carbide and the production of silicon carbide single crystals, but also sufficiently short to prevent excessive sublimation of silicon carbide.

In accordance with a preferred embodiment of the present invention, it may be provided that, following treatment stage (i) and prior to treatment stage (ii), the carbon- and silicon-containing solution or dispersion, in particular the SiC precursor sol, preferably the glass obtained in treatment stage (i), is cooled, in particular quenched. As a result of cooling, in particular quenching of the glass obtained, the amorphous glass state is preserved and frozen. In particular, it is possible in this way to obtain an ideal starting condition for the subsequent conversion to monocrystalline silicon carbide.

As far as the cooling rate in this context is concerned, this can vary naturally in wide ranges.

However, it has proven effective in the context of this invention if the carbon- and silicon-containing solution or dispersion, in particular the SiC precursor sol, preferably the glass obtained in treatment stage (i), is cooled with a cooling rate of more than 50° C./min, in particular more than 70° C./min, preferably more than 100° C./min.

Usually, in the context of the present invention, at least treatment stages (i) and (ii) are carried out in a protective gas atmosphere, in particular an inert gas atmosphere. In accordance with a preferred embodiment of the present invention, in particular the entire method step (b) is carried out in a protective gas atmosphere, in particular an inert gas atmosphere, with particular preference being given to both method steps (a) and (b) being carried out in a protective gas atmosphere, in particular an inert gas atmosphere.

In the context of the present invention, a protective gas is a gas which effectively prevents the oxidation of the components of the carbon- and silicon-containing solution or dispersion by, in particular, atmospheric oxygen, while an inert gas in the context of the present invention is a gas which does not react with the components of the carbon- and silicon-containing solution or dispersion under the process conditions. For example, nitrogen can be used as a protective gas in this invention, but not as an inert gas, since gaseous nitrogen can be incorporated into the silicon carbide structure, particularly in the form of nitrides. If, however, doping with nitrogen is desired, it is also possible to carry out the process according to the invention in a nitrogen atmosphere. In the context of the present invention, the protective gas is usually selected from noble gases and nitrogen and their mixtures, in particular argon and nitrogen and their mixtures. It is particularly preferred in the context of this invention if the protective gas is argon.

In the context of the present invention, it may also be provided that the substrate is removed after the thermal treatment, especially after method step (b).

If the substrate is removed in the context of the present invention, it has proven successful if the substrate is removed by oxidation. Usually the substrate is removed thermally or chemically, especially thermally or chemically oxidatively. In this context, particularly good results are obtained if the substrate is removed in an oxygen atmosphere, by ozone and/or by the impact of aqueous hydrogen peroxide solution. During oxidative removal in an oxygen atmosphere, the substrate is burnt, so to speak, which is particularly suitable for substrates based on graphite.

The removal of the substrate allows in particular the production of near-to two-dimensional silicon carbide bodies or silicon carbide wafers.

In accordance with a preferred embodiment of the present invention, the subject of the present invention is a method for producing thin layers of silicon carbide, in particular as described above, wherein
(a) in a first method step, a liquid carbon- and silicon-containing solution or dispersion, in particular a SiC precursor sol, is applied to a substrate,
(b) in a second method step following the first method step (a), the carbon- and silicon-containing solution or dispersion, in particular the SiC precursor sol, is converted to silicon carbide, in particular subjected to a thermal treatment, wherein
(i) in a first thermal treatment stage the carbon- and silicon-containing solution or dispersion, in particular the SiC precursor sol, is heated to temperatures in the range from 800 to 1,200° C., in particular 900 to 1,100° C., preferably 950 to 1,050° C., and
(ii) in a second treatment stage following the first thermal treatment stage (i), the carbon- and silicon-containing solution or dispersion, in particular the SiC precursor sol, is heated to temperatures of 1,800° C. or higher, and
(c) the substrate is removed in a third method step following the second method step (b).

In this context, the thickness of the wafer is generally determined by the layer thickness of the liquid carbon- and silicon-containing solution or dispersion, in particular the SiC precursor sol.

To produce silicon carbide wafers with particularly large thicknesses, the method steps (a) and (b) are repeated until a wafer of the desired thickness is obtained. In this way, monocrystalline silicon carbide wafers of almost any thickness can be easily obtained.

In accordance with a preferred embodiment of the present invention, the method steps (a) and (b) are repeated, whereby in every step different carbon- and silicon-containing solutions or dispersions are used, in particular SiC precursor sols, preferably with different doping reagents and/or different concentrations of doping reagents. By using different carbon- and silicon-containing solutions or dispersions, in particular SiC precursor sols, during the respective method steps (a) and (b), semiconductor materials with different electronic properties in different layers can be obtained, which can be used as base materials for electronic components. For example, layer sequences with pn doping for diodes and pnp or npn doping can be used as base materials for bipolar transistors.

All the advantages, features and particular as well as the preferred embodiments of the present invention can also be applied to this preferred embodiment of the present invention.

A further subject of the present invention—according to a second aspect of the present invention—is a composition, in particular a SiC precursor sol, in the form of a solution or dispersion, containing
(A) at least one silicon-containing compound,
(B) at least one carbon-containing compound,
(C) at least one solvent or dispersant; and
(D) optionally, doping reagents.

The composition according to the invention is particularly suitable for use as a carbon- and silicon-containing solution or dispersion, in particular SiC precursor sol, in the method according to the invention for producing thin layers of silicon carbide.

As far as the selection of the solvent or dispersant in the composition according to the invention is concerned, this can be selected from all suitable solvents or dispersants. Usually, however, the solvent or dispersant is selected from water and organic solvents and mixtures thereof. In particular in mixtures containing water, the usually hydrolysable or soluble starting compounds are converted to inorganic hydroxides, in particular metal hydroxides and silicas, which then condense so that precursors suitable for pyrolysis and crystallization are obtained.

In addition, the compounds used should have sufficiently high solubilities in the solvents used, in particular in ethanol and/or water, in order to be able to form finely divided dispersions of the solutions, in particular sols, and should not react with other constituents of the solution or dispersion, in particular the sol, to form insoluble compounds during the production process.

In addition, the reaction rate of the individual reactions is to be adjusted to each other, since hydrolysis, condensation and, if necessary, gelation of the composition according to the invention should take place undisturbed, if possible, in order to obtain the most homogeneous possible distribution of the individual components in the sol.

The reaction products formed should not be susceptible to oxidation and should not be volatile.

In the context of this invention, it can be intended that the organic solvent is selected from alcohols, in particular methanol, ethanol, 2-propanol, acetone, ethyl acetic ester and mixtures thereof. It is particularly preferred in this context if the organic solvent is selected from methanol, ethanol, 2-propanol and mixtures thereof, ethanol in particular being preferred.

The organic solvents mentioned above can be mixed with water in a wide range and are particularly suitable for dispersing or dissolving polar inorganic substances such as metal salts.

As explained above, the present invention uses mixtures of water and at least one organic solvent, in particular mixtures of water and ethanol, preferably as solvents or dispersion agents. In this context, it is preferred if the solvent or dispersant has a weight-related ratio of water to organic solvent of 1:10 to 20:1, in particular 1:5 to 15:1, preferably 1:2 to 10:1, more preferably 1:1 to 5:1, particularly preferred 1:3. The ratio of water to organic solvents allows the hydrolysis rate, in particular of the silicon-containing compound and of the doping reagents, to be adjusted on the one hand and the solubility and reaction rate of the carbon-containing compound, in particular of the carbon-containing precursor compound, such as sugar, on the other hand.

The quantity in which the composition contains the solvent or dispersion agent can vary widely depending on the respective application conditions and the type of doped or undoped silicon carbide to be produced. Usually, however, the composition comprises the solvent or dispersant in quantities of 10 to 80 wt. %, in particular 15 to 75 wt. %, preferably 20 to 70 wt. %, more preferably 20 to 65 wt. %, based on the composition.

In the context of the present invention, it is usually provided that the composition has a weight-related ratio of silicon to carbon, in particular in the form of the silicon-containing compound and the carbon-containing compound, in the range from 1:1 to 1:10, in particular 1:2 to 1:7, preferably 1:3 to 1:5, more preferably 1:3.5 to 1:4.5. Particularly good results are obtained in this context if the composition has a ratio by weight of silicon to carbon, in particular of silicon-containing compound to carbon-containing compound, of 1:4.

As far as the silicon-containing compound is concerned, it is preferred if the silicon-containing compound is selected from silanes, silane hydrolysates, orthosilicic acid and their mixtures, in particular silanes. In the context of this invention, orthosilicic acid and its condensation products can be obtained, for example, from alkali silicates whose alkali metal ions have been exchanged for protons by ion exchange. As far as possible, alkali metal compounds are not used in the composition of the present invention, since these are also incorporated into the silicon carbide-containing compound. Alkali metal doping, as a rule, is not desired within the scope of the present invention. However, if this should be desired, suitable alkali metal salts, for example of silicon-containing compounds or also alkali phosphates, can be used.

If a silane is used as a silicon-containing compound in the context of the present invention, it has proven advantageous if the silane is selected from silanes of the general formula I

R₄₋ₙSiXₙ (I)

with
R=alkyl, in particular C1- to C5-alkyl, preferably C1- to C3-alkyl, more preferably C1- and/or C2-alkyl;
Aryl, in particular C6- to C20-aryl, preferably C6- to C15-aryl, more preferably C6- to C10-aryl;
Olefin, in particular terminal olefin, preferably C2- to C10-olefin, more preferably C2- to C8-olefin, in particular preferably C2- to C5-olefin, in particular C2- and/or C3-olefin, in particular preferably vinyl;
Amine, especially C2- to C10-amine, preferably C2- to C8-amine, more preferably C2- to C5-amine, especially preferably C2- and/or C3-amine;
Carboxylic acid, in particular C2- to C10-carboxylic acid, more preferably C2- to C8-carboxylic acid, in particular preferably C2- to C5-carboxylic acid, particularly preferred C2- and/or C3-carboxylic acid;
Alcohol, in particular C2- to C10-alcohol, preferably C2- to C8-alcohol, more preferably C2- to C5-alcohol, in particular preferably C2- and/or C3-alcohol;
X=halide, in particular chloride and/or bromide;
alkoxy, especially C1- to C6-alkoxy, preferably C1- to C4-alkoxy, more preferably C1- and/or C2-alkoxy; and
n=1-4, preferably 3 or 4.

However, particularly good results are obtained if the silane is selected from silanes of the general formula Ia

R₄₋ₙSiXₙ (Ia)

with
R=C1- to C3-alkyl, in particular C1- and/or C2-alkyl;
C6- to C15-aryl, in particular C6- to C10-aryl;
C2- and/or C3-olefin, in particular vinyl;
X=alkoxy, in particular C1- to C6-alkoxy, preferably C1- to C4-alkoxy, more preferably C1- and/or C2-alkoxy; and
n=3 or 4.

By hydrolysis and subsequent condensation reaction of the aforementioned silanes, condensed orthosilicic acids or siloxanes can easily be obtained within the scope of the present invention. These have only very small particle sizes, whereby further elements, in particular metal hydroxides, can also be incorporated into the basic structure.

By using carbon- and silicon-containing solutions or dispersions, in particular SiC precursor sols, it is possible within the scope of the present invention to arrange the components of the silicon carbide to be produced in homogeneous and fine distribution as spatially as possible adjacent to each other, so that the individual components of the silicon carbide-containing target compound are present in the immediate vicinity of each other when energy is applied and thus do not have to diffuse comparatively long distances first.

Particularly good results are obtained in the context of the present invention if the silicon-containing compound is selected from tetraalkoxy silanes, trialkoxysilanes and mixtures thereof, preferably tetraethoxy silane, tetramethoxysilane or triethoxymethylsilane and mixtures thereof.

As far as the amounts in which the composition contains the silicon-containing compound are concerned, these can also vary widely depending on the respective application conditions. However, the composition usually contains the silicon-containing compound in quantities of 1 to 80 wt. %, in particular 2 to 70 wt. %, preferably 5 to 60 wt. %, more preferably 10 to 60 wt. %, based on the composition.

As stated above, the inventive composition contains at least one carbon-containing compound. All compounds which can either be dissolved or at least finely dispersed in the solvents used and which can release solid carbon during pyrolysis can be considered as carbon-containing compounds. The carbon-containing compound is also preferably able to reduce metal hydroxides to elemental metal under process conditions.

In the context of the present invention, it has proven successful if the carbon-containing compound is selected from the group of sugars, in particular sucrose, glucose, fructose, invert sugar, maltose; starch; starch derivatives; organic polymers, in particular phenol-formaldehyde resin and resorcinol-formaldehyde resin, and mixtures thereof.

Particularly good results are obtained in the context of the present invention if the carbon-containing compound is selected from the group of sugars; starch, starch derivatives and their mixtures, preferably sugars, since the viscosity of the composition can be specifically adjusted, in particular by using sugars and starch or starch derivatives.

As far as the quantity in which the composition contains the carbon-containing compound is concerned, this can also vary over a wide range depending on the respective application and application conditions or the target compounds to be produced. Usually, however, the composition contains the carbon-containing compound in quantities of 5 to 50 wt. %, in particular 10 to 40 wt. %, preferably 10 to 35 wt. %, more preferably 12 to 30 wt. %, based on the composition.

In the context of the present invention, the composition may contain a doping reagent. If the composition comprises a doping reagent, the composition usually comprises the doping reagent in amounts of 0.000001 to 15 wt. %, in particular 0.000001 to 10 wt. %, preferably 0.000005 to 5 wt. %, more preferably 0.00001 to 1 wt. %, based on the solution or dispersion. The properties of the resulting silicon carbide can be decisively changed by the addition of doping reagents.

If the silicon carbide is to be doped with nitrogen, nitric acid, ammonium chloride or melamine, for example, can be used as doping reagents. In the case of nitrogen, it is also possible to carry out the additive manufacturing process in a nitrogen atmosphere, in which case doping with nitrogen can also be achieved, but is less accurate. Further doping reagents are mentioned in particular in connection with the description of the method according to the invention.

For further details on the composition according to the invention, reference may be made to the above explanations on the method according to the invention in order to avoid unnecessary repetitions, which apply accordingly with regard to the inventive composition.

Finally, according to a third aspect of the present invention, another subject of the present invention is a silicon carbide layer, in particular a monocrystalline silicon carbide layer, obtainable by the method described above and/or using the composition described above.

For further details on the silicon carbide layer in accordance with the invention, reference is made to the above explanations on the other aspects of the invention, which apply accordingly to the silicon carbide layer in accordance with the invention.

1. Method of producing thin layers of silicon carbide,
characterized in that
(a) in a first method step, a liquid carbon- and silicon-containing solution or dispersion, in particular a SiC precursor sol, is applied to a substrate and
(b) in a second method step following the first method step (a), the carbon- and silicon-containing solution or dispersion, in particular the SiC precursor sol, is converted to silicon carbide.

2. Method according to claim 1, characterized in that in the first method step (a) the carbon- and silicon-containing solution or dispersion, in particular the SiC precursor sol, is applied to the substrate as a layer, in particular as a homogeneous layer.

3. Method according to claim 1, characterized in that in method step (a) the carbon- and silicon-containing solution or dispersion, in particular the SiC precursor sol, is applied to the substrate by a coating method, in particular by dip-coating, spin-coating, spraying or rolling, preferably by dip-coating, spin-coating or spraying, preferably by dip-coating.

4. Method according to claim 1, characterized in that in method step (a) the carbon- and silicon-containing solution or dispersion, in particular the SiC precursor sol is applied to the substrate with a layer thickness in the range from 0.1 to 1,000 μm, in particular from 0.5 to 500 μm, preferably from 0.8 to 300 μm, more preferably from 1 to 100 μm.

5. Method according to claim 1, characterized in that the carbon- and silicon-containing solution or dispersion, in particular the SiC precursor sol, has a dynamic viscosity according to Brookfield at 25° C. in the range from 3 to 500 mPas, in particular from 4 to 200 mPas, preferably from 5 to 100 mPas.

6. Method according to claim 1, characterized in that the carbon- and silicon-containing solution or dispersion, in particular the SiC precursor sol, contains
(A) at least one silicon-containing compound,
(B) at least one carbon-containing compound; and
(C) at least one solvent or dispersant.

7. Method according to claim 1, characterized in that substrate is selected from crystalline and amorphous substrates, in particular amorphous substrates.

8. Method according to claim 1, characterized in that the material of the substrate is selected from carbon, in particular graphite, and ceramic materials, in particular silicon carbide, silicon dioxide, aluminum oxide, as well as metals and mixtures thereof.

9. Method according to claim 1, characterized in that in method step (b) the carbon- and silicon-containing solution or dispersion, in particular the SiC precursor sol, after application to the substrate, is subjected to a thermal treatment, in particular a multistage thermal treatment.

10. Method according to claim 9, characterized in that, during thermal treatment
(i) in a first thermal treatment stage, the carbon- and silicon-containing solution or dispersion, in particular the SiC precursor sol, is heated to temperatures in the range from 800 to 1,200° C., in particular 900 to 1,100° C., preferably 950 to 1,050° C., and
(ii) in a second thermal treatment stage following the first thermal treatment stage (i), the carbon- and silicon-containing solution or dispersion, in particular the SiC precursor sol, is heated to temperatures of 1,800° C. or higher.

11. Method according to claim 10, characterized in that in treatment stage (i) the carbon- and silicon-containing solution or dispersion, in particular the SiC precursor sol, is converted into a glass.

12. Method according to claim 10, characterized in that in treatment stage (ii) the carbon- and silicon-containing solution or dispersion, in particular the SiC precursor sol, preferably the glass obtained in treatment stage (i), is converted into crystalline silicon carbide.

13. Method according to claim 10, characterized in that, following treatment stage (i) and before treatment stage (ii) is carried out, the carbon- and silicon-containing solution or dispersion, in particular the SiC precursor sol, preferably the glass obtained in treatment stage (i), is cooled, in particular quenched.

14. Method according to claim 1, characterized in that the substrate is removed following the thermal treatment, in particular following method step (b).

15. Method according to claim 1, characterized in that the method steps (a) and (b) are repeated, in particular wherein different carbon- and silicon-containing solutions or dispersions, in particular SiC precursor sols, preferably with different doping reagents and/or different concentrations of doping reagents, are used in each step.

16. Composition, in particular SiC precursorsol, in the form of a solution or dispersion, containing
(A) at least one silicon-containing compound,
(B) at least one carbon-containing compound,
(C) at least one solvent or dispersant; and
(D) optionally, doping reagents.

17. Composition according to claim 16, characterized in that the solvent or dispersant is selected from water and organic solvents and mixtures thereof.

18. Composition according to claim 16, characterized in that the composition has a weight-related ratio of silicon to carbon in the range from 1:1 to 1:10, in particular 1:2 to 1:7, preferably 1:3 to 1:5, more preferably 1:3.5 to 1:4.5.

19. Composition according to one of claim 16, characterized in that the silicon-containing compound is selected from silanes, silane hydrolysates, orthosilicic acid and mixtures thereof, in particular silanes.

20. Composition according to claim 16, characterized in that the carbon-containing compound is selected from the group of sugars, in particular saccharose, glucose, fructose, invert sugar, maltose; starch; starch derivatives; organic polymers, in particular phenol-formaldehyde resin and resorcinol-formaldehyde resin, and mixtures thereof.

21. Silicon carbide layer, in particular monocrystalline silicon carbide layer, obtainable by a method according to claim 1 and/or using a composition according to claim 16.
